(19) United States
(12) Patent Application Publication
(10) Pub. No.: US 2018/0278859 A1
(43) Pub. Date: Sep. 27, 2018

(54) IMAGE SENSOR AND IMAGE-CAPTURING DEVICE

(71) Applicant: NIKON CORPORATION, Tokyo (JP)

(72) Inventors: Takayuki SUGA, Tokyo (JP); Toru IWANE, Yokohama-shi (JP); Masao NAKAJIMA, Kawasaki-shi (JP)

(73) Assignee: NIKON CORPORATION, Tokyo (JP)

(21) Appl. No.: 15/761,799

(22) PCT Filed: Sep. 23, 2016
(86) PCT No.: PCT/JP2016/078034

§ 371 Date: Mar. 20, 2018

(30) Foreign Application Priority Data
Sep. 25, 2015 (JP) 2015-188248

(51) Int. Cl. H04N 5/343; H01L 25/18; H01L 27/30; H01L 27/146; H04N 9/097; H04N 5/369

(52) U.S. Cl. CPC H04N 5/343; H01L 25/18; H01L 27/307; H04N 5/369; H01L 27/14621; H01L 27/14645; H04N 9/097; H01L 27/14627

(57) ABSTRACT

An image sensor includes: a first image-capturing unit that includes a plurality of first photoelectric conversion units that perform photoelectric conversion for light at a part of wavelength in incident light and at each of which light at another wavelength in the incident light is transmitted; a plurality of lenses at which the light having been transmitted through the first image-capturing unit enters; and a second image-capturing unit that includes a plurality of second photoelectric conversion units, disposed in correspondence to each of the plurality of lenses, that performs photoelectric conversion for incident light.

### TECHNICAL FIELD

The present invention relates to an image sensor and an image-capturing device.

### BACKGROUND ART

There is an image-capturing device known in the related art that has a standard photographing mode and a refocus photographing mode (see PTL1). There is an issue yet to be addressed in the related art in that full deliberation is not made with regard to the color of light received at the two image sensors.

### CITATION LIST

### Patent Literature

PTL 1: Japanese Laid Open Patent Publication No. 2009-17079

### SUMMARY OF INVENTION

According to the 1st aspect of the present invention, an image sensor comprises: a first image-capturing unit that includes a plurality of first photoelectric conversion units that performs photoelectric conversion for light at a part of wavelength in incident light and at each of which light at another wavelength in the incident light is transmitted; a plurality of lenses at which the light having been transmitted through the first image-capturing unit enters; and a second image-capturing unit that includes a plurality of second photoelectric conversion units, disposed in correspondence to each of the plurality of lenses, that performs photoelectric conversion for incident light.

According to the 2nd aspect of the present invention, an image-capturing device comprises: the image sensor according to the 1st aspect; and an image processing unit that generates first image data based upon signals from the first image-capturing unit and generates second image data, expressed with fewer pixels than the first image data, based upon signals from the second image-capturing unit.

### BRIEF DESCRIPTION OF DRAWINGS

FIG. 1 An illustration of the essential structure assumed in a camera

FIG. 2 A perspective showing the optical system of the camera

FIG. 3 A sectional view of the first image-capturing element, the microlens array and the second image-capturing element

FIG. 4 A front view of the image sensor in FIG. 3, taken from the Z+ side axis

FIG. 5 A diagram indicating the wavelength range of the light that undergoes photoelectric conversion at pixels in the photoelectric conversion element array, presented in FIG. 5(a), and a diagram indicating the wavelength range of the light that undergoes photoelectric conversion at pixels in the light-receiving element array, presented in FIG. 5(b)

FIG. 6 A flowchart of camera processing that may be executed by the control unit

FIG. 7 A sectional view illustrating the structure of one of the plurality of micromirrors configuring a micromirror array

### DESCRIPTION OF EMBODIMENTS

(Overview of the Image-Capturing Device)

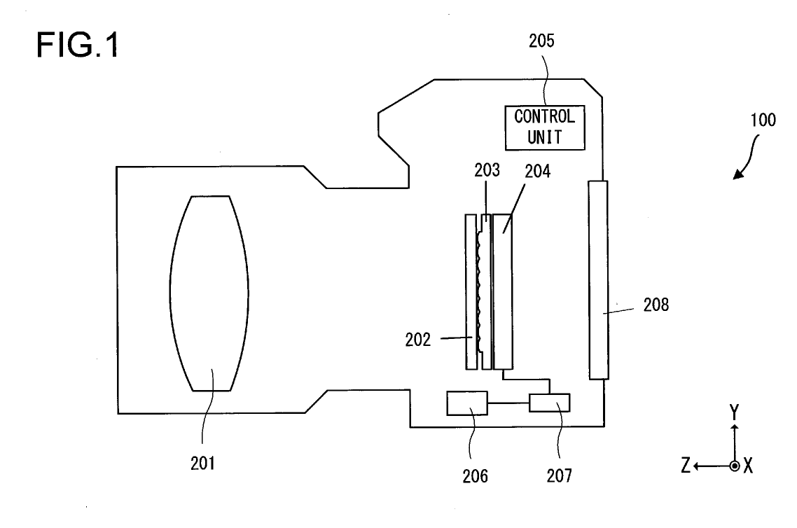

FIG. 1 illustrates the essential structure in a camera 100 in an embodiment. Light departing a subject advances toward the negative side along a Z axis among the coordinate axes shown in FIG. 1. It is to be noted that a direction running upward perpendicular to the Z axis will be referred to as a Y axis + direction and a direction running toward the viewer at a right angle to the drawing sheet and perpendicular to both the Z axis and Y axis will be referred to as an X axis + direction. In some of the drawings to be referred to subsequently, specific directions will be indicated in reference to the coordinate axes in FIG. 1.

An image-capturing lens 201 in FIG. 1 is an interchangeable lens that is mounted at the body of the camera 100 when in use. It is to be noted that the image-capturing lens 201 may instead be configured as an integrated part of the body of the camera 100.

The camera 100 includes a first image-capturing element (image-capturing unit) 202 and a second image-capturing element (image-capturing unit) 204, and is capable of capturing a plurality of images in a single shot. The image-capturing lens 201 guides light having departed the subject toward the first image-capturing element 202. The first image-capturing element 202, which is translucent, performs photoelectric conversion (absorption) for part of the subject light having entered therein and some of the subject light having entered therein (the light that has not been absorbed) is transmitted.

A microlens array 203 is disposed in close proximity to (or is in contact with) the surface of the first image-capturing element 202 located on the Z axis − side. The light having been transmitted through the first image-capturing element 202 enters the microlens array 203.

The microlens array 203 is configured with microlenses (microlenses L to be described later) disposed in a two-dimensional array in a lattice pattern or a honeycomb pattern. The second image-capturing element 204 is disposed along the Z axis − direction relative to the microlens array 203. The subject light having passed through the microlens array 203 enters the second image-capturing element 204. The second image-capturing element 204 performs photoelectric conversion for the subject light having entered therein.

A control unit 205 controls image-capturing operation executed in the camera 100. Namely, it executes drive control when the first image-capturing element 202 and the second image-capturing element 204 are engaged in photoelectric conversion, control for readout of pixel signals, resulting from the photoelectric conversion, from the first image-capturing element 202 and the second image-capturing element 204, and the like.

The pixel signals individually read out from the first image-capturing element 202 and the second image-capturing element 204 are provided to an image processing unit 207. At the image processing unit 207, the pixel signals from the two image sensors undergo predetermined types of image processing. Image data resulting from the image processing are recorded into a recording medium 206 such as a memory card.

It is to be noted that the pixel signals individually read out from the first image-capturing element 202 and the second image-capturing element 204 may be recorded directly as “raw” data into the recording medium 206 without undergoing any image processing.

An image reproduced based upon image data, an operation menu screen and the like are displayed at a display unit 208. The control unit 205 executes display control for the display unit 208.

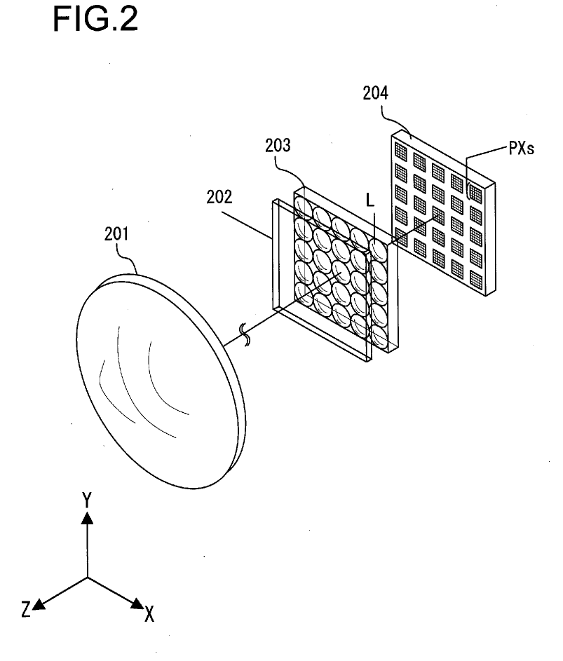

FIG. 2 is a perspective of an optical system of the camera 100, i.e., the system configured with the image-capturing lens 201, the first image-capturing element 202, the microlens array 203 and the second image-capturing element 204. The first image-capturing element 202 is disposed on a predetermined focal plane of the image-capturing lens 201.

It is to be noted that while the first image-capturing element 202, the microlens array 203 and the second image-capturing element 204 are shown with significant distances separating them in the figure for clarity, the first image-capturing element 202 and the microlens array 203 are in fact disposed in close contact with each other. In addition, the distance between the first image-capturing element 202 and the second image-capturing element 204 is set in correspondence to the focal length of the microlenses L constituting the microlens array 203.

<Standard Image>

The first image-capturing element 202 in the camera 100 described above captures a subject image projected via the image-capturing lens 201 onto the first image-capturing element 202. In this description, the image captured by the first image-capturing element 202 will be referred to as a standard image.

<Light Field Image>

The second image-capturing element 204 in the camera 100 captures an image formed with the light transmitted through the first image-capturing element 202. The second image-capturing element 204 is configured so as to capture a plurality of images with varying viewpoints through the light field photography technology.

Light originating from different areas of the subject enters the individual microlenses L in the microlens array 203 in FIG. 2. In other words, the light having entered the microlens array 203 is divided into a plurality of parts via the microlenses L configuring the microlens array 203. Each part of the light having passed through a micro lens L then enters a pixel group PXs at the second image-capturing element 204, which is disposed to the rear (along the Z axis − direction) of the corresponding microlens L.

It is to be noted that while the microlens array 203 is configured with 5×5 microlenses L in the example presented in FIG. 2, the microlens array 203 may be configured with microlenses L disposed in a number other than that shown in the figure.

The light having been transmitted through each micro lens L is divided into a plurality of parts at the pixel group PXs in the second image-capturing element 204, which is disposed to the rear (along the Z axis − direction) of the particular micro lens L. Namely, individual pixels in the pixel groups PXs each receive light having departed a specific area of the subject and having passed through a specific area different from any other areas of image-capturing lens 201.

The structure configured as described above makes it possible to obtain small images representing the light quantity distribution that indicates areas of the image-capturing lens 201 through which the subject light has passed, corresponding to various parts of the subject, in a number corresponding to the number of microlenses L. A collection of such small images will be referred to as a light field (LF) image in this description.

The direction along which light enters each pixel among the plurality of pixels arrayed to the rear of (along the Z axis − direction) of each micro lens L in the second image-capturing element 204 is determined in correspondence to the position taken by the particular pixel. Namely, the positional relationship between the microlens L and each pixel in the second image-capturing element 204 disposed behind it is known in advance as design information, and thus, the direction along which a ray of light enters the particular pixel via the microlens L (direction information) can be ascertained. Accordingly, a pixel signal output from the pixel at the second image-capturing element 204 indicates the intensity of light (light ray information) that enters the pixel along the predetermined direction.

In this description, light that enters a pixel in the second image-capturing element 204 along the predetermined direction will be referred to as a light ray.

<Refocus Processing>

The data expressing an LF image are generally used for image refocus processing. The term “refocus processing” is used to refer to processing through which an image at a given focusing position or viewpoint is generated by executing an arithmetic operation (an arithmetic operation for rearranging light rays) based upon the light ray information and the direction information mentioned earlier, which are included in the LF image. In the description, an image generated at a given focusing position or viewpoint through the refocus processing will be referred to a refocus image. Since such refocus processing (may otherwise be referred to as reconstruction processing) is of the known art, a detailed explanation of the refocus processing will not be provided.

It is to be noted that the refocus processing may be executed by the image processing unit 207 within the camera 100, or it may be executed by an external device, such as a personal computer, with the LF image data recorded in the recording medium 206 transmitted thereto.

<Structure of the Image Sensor>

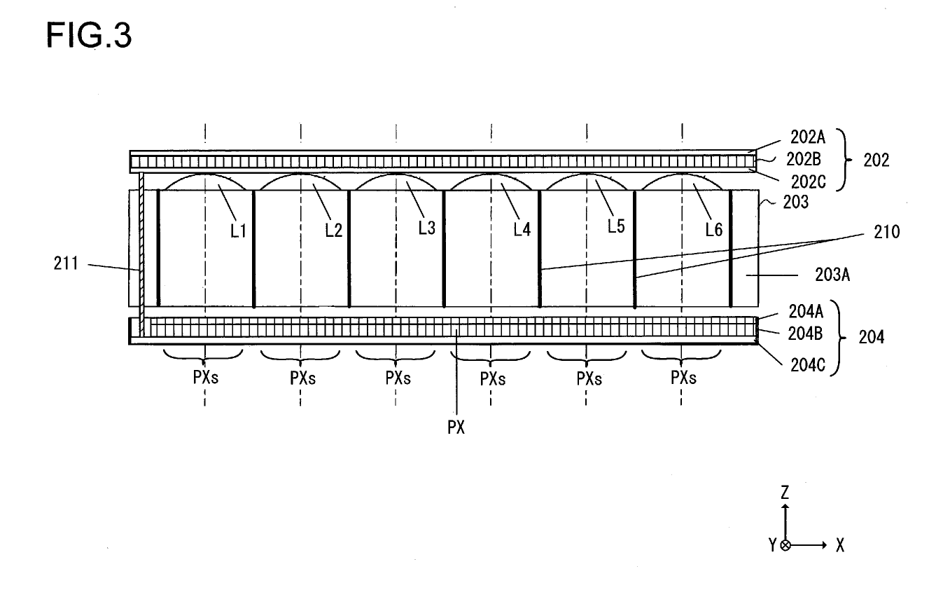

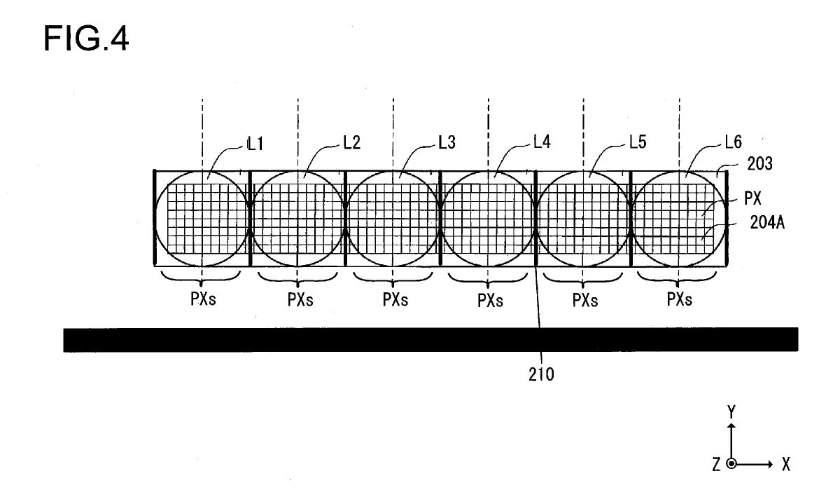

Next, an example of a structure that may be adopted for the image sensor in the camera 100 will be described. The embodiment will be explained in reference to an example in which pixel signals resulting from the photoelectric conversion are read out independently from the first image-capturing element 202 and the second image-capturing element 204. FIG. 3 presents a sectional view of the first image-capturing element 202, the microlens array 203 and the second image-capturing element 204, taken over a plane ranging parallel to the X-Z plane. FIG. 4 is a front view of the image sensor in FIG. 3 taken from the Z axis + direction.

In FIG. 3 and FIG. 4 the image sensor includes a structure achieved by combining the first image-capturing element 202, the microlens array 203 and the second image-capturing element 204. Pixel signals expressing a standard image are read out from the first image-capturing element 202. Pixel signals expressing an LF image are read out from the second image-capturing element 204.

<First Image-Capturing Element>

The first image-capturing element 202 adopts a structure that includes a readout circuit layer 202C formed on a transparent substrate, a photoelectric conversion element array 202B and a transparent electrode layer 202A, laminated in this order starting on the Z axis − side.

The transparent electrode layer 202A is used to apply voltage to photoelectric conversion elements in the photoelectric conversion element array 202B. The transparent electrode layer 202A may be formed by using any of various types of optical materials assuring a high degree of transparency to visible light. Examples of such optical materials include an inorganic transparent electrode film such as an indium-tin oxide film (ITO) and an organic transparent conductive film such as polyethylene dioxy-thiophene polystyrene sulphonate (PEDT/PSS).

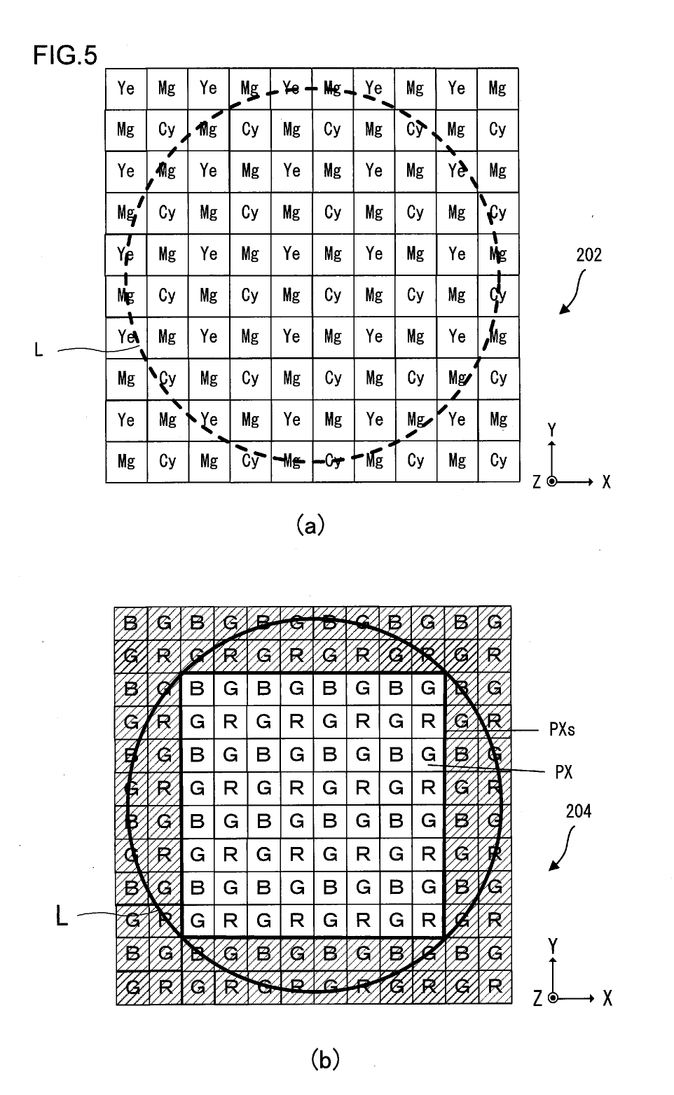

FIG. 5(a) indicates the wavelength range of light that undergoes photoelectric conversion at pixels in the photoelectric conversion element array 202B. The photoelectric conversion element array 202B is configured with a plurality of photoelectric conversion elements, each demonstrating peak sensitivity to light over, for instance, a Ye (yellow) wavelength range, an Mg (magenta) wavelength range or a Cy (cyan) wavelength range, arranged in a two-dimensional array pattern, as shown in FIG. 5(a)

The pixels in the photoelectric conversion element array 202B are each constituted with a photoelectric conversion element formed by using an organic photoelectric conversion material. For instance, in each odd-numbered row, organic photoelectric films that perform photoelectric conversion for Ye light and Mg light may be alternately disposed at positions corresponding to the individual pixels, whereas organic photoelectric films that perform photoelectric conversion for Mg light and Cy light may be disposed alternately at positions corresponding to the individual pixels in each even-numbered row.

The photoelectric conversion element disposed at each pixel position absorbs light in the specific wavelength range that is to undergo the photoelectric conversion, but light that is not in the wavelength range to undergo photoelectric conversion is allowed to be transmitted. Namely, a pixel that performs photoelectric conversion for Ye light allows B (blue) light, which is complementary to Ye, to be transmitted. A pixel that performs photoelectric conversion for Mg light allows G (green) light, which is complementary to Mg, to be transmitted. Likewise, a pixel that performs photoelectric conversion for Cy light allows R (red) light, which is complementary to Cy, to be transmitted.

Reference sign L in FIG. 5(a) indicates a single microlens in the microlens array 203 disposed to the rear (along the Z axis − direction) of the first image-capturing element 202. B light, G light and R light, having been transmitted through the photoelectric conversion elements in the photoelectric conversion element array 202B, enter the micro lens L disposed to the rear. Namely, photoelectric conversion elements disposed at a plurality of pixel positions in the first image-capturing element 202 correspond to each microlens L.

The readout circuit layer 202C includes pixel electrodes (not shown) and a readout circuit that reads out the pixel signals resulting from the photoelectric conversion at the photoelectric conversion element array 202B. The pixel electrodes are each constituted of an optical material with a high level of transparency to allow transmission of visible light. Examples of such an optical element include an inorganic transparent electrode material such as an indium-tin oxide (ITO) film or an organic transparent conductive film such as PEDT/PSS, both mentioned earlier. In addition, the readout circuit may be configured with a thin film transistor (TFT) array.

It is to be noted that microlenses other than those in the microlens array 203 may be disposed each in correspondence to one of the pixel positions (on the image-capturing lens side) in the photoelectric conversion element array 202B, so as to allow light to enter the individual photoelectric conversion elements taking up the various pixel positions in greater amounts.

<Microlens Array>

The microlens array 203 shown in FIG. 3 and FIG. 4 includes microlenses L1 through L6 formed as integrated parts of a transmissive substrate 203A. The transmissive substrate 203A may be constituted with, for instance, a glass substrate, a plastic substrate or a silica substrate. The microlens array 203 may be formed through, for instance, injection molding or pressure molding.

It is to be noted that the microlenses L1 through L6 may be formed as members separate from the transmissive substrate 203A.

In addition, the surface of the microlens array 203 located on the Z axis − side may be bonded to the second image-capturing element 204 so as to allow it to function as a package member of the second image-capturing element 204. In such a case, the second image-capturing element 204 does not require a special package member constituted of glass, resin or the like, to be disposed at a position further toward the Z axis + side relative to the microlens array 203.

The transmissive substrate 203A of the microlens array 203 has a thickness corresponding to the focal length of the microlenses L1 through L6. For instance, the thickness of the transmissive substrate 203A may be set to 0.3 mm to several millimeters.

<Second Image-Capturing Element>

The second image-capturing element 204 in FIG. 3 may be constituted with a standard-use CCD image sensor, CMOS image sensor or the like. The second image-capturing element 204 includes a light-receiving element array 204B formed on a silicon substrate 204C and a color filter array 204A laminated in this order starting on the Z axis − side.

FIG. 5(b) is a diagram indicating the wavelength range of light that undergoes photoelectric conversion at the pixels in the light-receiving element array 204B. As explained earlier, B light, G light or R light is transmitted through each photoelectric conversion element in the photoelectric conversion element array 202B (the first image-capturing element 202). The embodiment adopts the structure that would allow B light, G light and R light to enter as mixed light at each of the various pixels PX making up the pixel group PXs disposed to the rear (along the Z axis − direction) relative to the microlens L in FIG. 5(b). For this reason, a color filter array 204A is disposed in the second image-capturing element 204.

The color filter array 204A in FIG. 3 has a structure that includes a plurality of filters through which light in the RGB (red, green and blue) wavelength ranges, for instance, is selectively transmitted, arranged in a two-dimensional array pattern, as shown in FIG. 5(b). At the color filter array 204A, filters are disposed each in correspondence to the position taken by a pixel PX in the light-receiving element array 204B. For instance, filters through which B light and G light are transmitted may be disposed at alternate positions corresponding the individual pixel positions in each odd-numbered row, whereas filters through which G light and R light are transmitted may be disposed at alternate positions corresponding the individual pixel positions in each even-numbered row.

A light-receiving element such as a photodiode is disposed at each pixel PX in the light-receiving element array 204B. At the light-receiving element array 204B, a plurality of pixels PX are formed in a two-dimensional array pattern, as shown in FIG. 4 and FIG. 5(b). The light-receiving element array 204B includes charge transfer electrodes disposed between the pixels PX and a light shielding film formed over the charge transfer electrodes (neither shown). B light, G light or R light enters each pixel PX via the color filter array 204A described above. Each pixel PX generates an electric charge corresponding to the amount of light having entered the corresponding photodiode. Electric charges accumulated in the individual pixels PX are sequentially transferred via transfer transistors (not shown) to the charge transfer electrodes and are sequentially read out.

The second image-capturing element 204 in the embodiment is a back side illumination-type sensor with the photodiodes at the pixels PX disposed on the back side (Z axis + side) of the charge transfer electrodes. Under normal circumstances, a greater area can be taken for the openings to the photodiodes in a back side illumination sensor, compared to that at a front side illumination sensor, and accordingly, the amount of light to undergo photoelectric conversion at the second image-capturing element 204 can be maximized by adopting the back side illumination structure. At this second image-capturing element, light retaining sufficient intensity can be allowed to enter the individual pixels PX without having to dispose a condenser lens in correspondence to each pixel PX. This means that a structure that does not include any other lenses disposed in the area between the microlens array 203 and the second image-capturing element 204 can be obtained. As a result, the surface of the second image-capturing element 204 on the Z axis + side can be planarized, which makes it possible to bond the microlens array 203 to the second image-capturing element 204 with ease.

The microlenses L1 through L6 in FIG. 4 are disposed to the rear (along the Z axis − direction) relative to the first image-capturing element 202. The color filter array 204A of the second image-capturing element 204 takes a position to the rear (along the Z axis − direction) relative to the microlenses L1 through L6. The diagram in FIG. 5 (b) is an enlarged illustration of the structure of the color filter array corresponding to a single microlens. A plurality of pixels PX are formed in a two-dimensional array pattern at the light-receiving element array 204B in the second image-capturing element 204, with a pixel group PXs made up with a predetermined number of pixels PX allocated to each of the microlenses L1 through L6.

It is to be noted that in FIG. 5(b), the pixels PX in the pixel group PXs, among the plurality of pixels PX, are indicated as unshaded pixels, whereas the pixels that are not part of the pixel group PXs are indicated as shaded pixels.

While the pixel group PXs allocated in correspondence to each micro lens L1 through L6 is made up with 8×8 pixels in the example presented in FIG. 4 and FIG. 5(b), the number of pixels PX to make up each pixel group PXs is not limited to this example. In addition, the number of microlenses L1 through L6 is not limited to that in FIG. 4, either. Furthermore, the pixels PX may be disposed at the light-receiving element array 204B so as to form pixel groups PXs at positions separated from one another, each in correspondence to a microlens L, as shown in FIG. 2, or the plurality of pixels PX may be disposed in a two-dimensional array pattern without separating one pixel group PXs from another pixel group PXs, as shown in FIG. 4 and FIG. 5(b).

In the embodiment, in the relationship between the pixel interval (pitch) at the first image-capturing element 202 and the pixel interval (pitch) at the second image-capturing element 204, the pixel interval at the first image-capturing element 202 is set greater than the pixel interval at the second image-capturing element 204, in order to minimize the occurrence of diffraction of light in the visible light band. It is desirable to set the pixel interval at the first image-capturing element 202 to at least 4 μm and it is even more desirable to set the interval to 20 μm or greater. The term “pixel interval” refers to the distance between the center points of two adjacent pixels.

<Control>

The control unit 205 executes control for raising the signal level of the pixel signals expressing the LF image obtained via the second image-capturing element 204 by raising the sensitivity of the second image-capturing element 204 or lengthening the exposure time (electric charge accumulation time).

Such control is executed because even though the second image-capturing element 204 gas the back side illumination structure, the size of the pixels at the second image-capturing element 204 is smaller than the pixel size at the first image-capturing element 202 and the signal level of the pixel signals expressing the LF image to be obtained via the second image-capturing element is still lower than the signal level of the pixel signals expressing the standard image.

The control unit 205 determines the sensitivity of the second image-capturing element 204 based upon the pixel signal level obtained at the first image-capturing element 202. It may, for instance, adjust the sensitivity of the second image-capturing element 204 to a higher level if the pixel signal level obtained at the first image-capturing element 202 is lower or adjust the sensitivity of the second image-capturing element 204 so as to set the pixel signal level at the second image-capturing element 204 closer to the pixel signal level obtained at the first image-capturing element 202.

In addition, the control unit 205 determines the electric charge accumulation time at the second image-capturing element 204 based upon the pixel signal level obtained at the first image-capturing element 202. For instance, it may adjust the electric charge accumulation time at the second image-capturing element 204 to a greater value if the pixel signal level obtained at the first image-capturing element 202 is lower or adjust the electric charge accumulation time at the second image-capturing element 204 so as to set the pixel signal level at the second image-capturing element 204 closer to the pixel image signal obtained at the first image-capturing element 202.

<Recording>

The recording unit 205 generates an image file to be recorded into the recording medium 206. In a standard photographing mode to record a standard image only, the control unit 205 includes standard image data generated based upon pixel signals read out from the first image-capturing element 202 in the image file.

In an LF photographing mode to record an LF image, the control unit 205 includes LF image data generated based upon pixel signals read out from the second image-capturing element 204 in the image file. The LF image data in the image file may include data of an image (refocus image) at a given focusing position or viewpoint, generated through the refocus processing. In this situation, the LF image data and the refocus image data can be included in the image file as a plurality of sets of related image data.

When generating an image file containing a plurality of sets of related image data, it is desirable to adopt a multi-picture format. In other words, the plurality of sets of related image data should be put in an image file adopting the multi picture format.

As an alternative, when generating an image file containing a plurality of sets of related image data, a plurality of image files sharing a single file name with different extension names from one another may be generated and each of the plurality of sets of related image data may be put into one of the plurality of image files. For instance, an image file for the LF image data and an image file for the refocus image data may be generated so as to share a single file name with different extension names. Since they share the same file name, the user is able to ascertain with ease that they contain related image data.

Under normal circumstances, a plurality of refocus images corresponding to a plurality of focusing positions can be generated based upon LF image data. Since a significant number of related images are bound to be created when a plurality of sets of refocus image data are generated in correspondence to a plurality of focusing positions based upon the LF image data, it is desirable to allow the user to handle the image data with better ease by using an image file in the multi-picture format or a plurality of image files sharing the same file name but bearing different extension names.

In addition to the standard photographing mode for recording a standard image and the LF photographing mode for recording an LF image, a dual photographing mode for recording both standard image data and LF image data may be available through the control unit 205. In the dual photographing mode, in which both standard image data and LF image data are recorded, the standard image data and the LF image data are recorded as a plurality of sets of related image data. In this mode, too, it is desirable to allow the user to handle the image data more easily by using an image file in the multi picture format or a plurality of image files sharing the same file name with different extension names, as explained earlier.

<Flowchart>

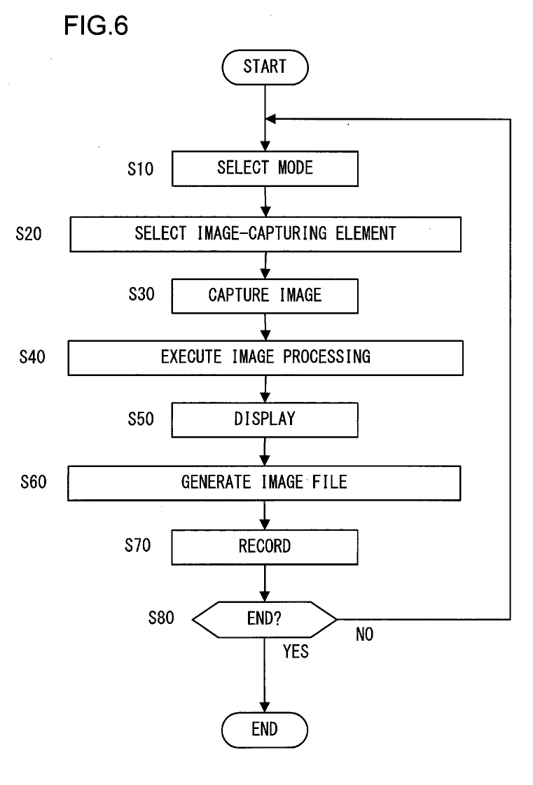

FIG. 6 presents a flowchart of the camera processing executed by the control unit 205. The control unit 205 executes a program enabling the processing shown in FIG. 6 when the main switch is turned on or when a restart operation is performed in the sleep state. In step S10 in FIG. 6, the control unit 205 selects a mode. Based upon, for instance, a setting state of an operation member (not shown), the control unit 205 makes a decision as to which mode among the standard photographing mode, the LF photographing mode and the dual photographing mode is to be selected and then the operation proceeds to step S20.

Instead of selecting a mode based upon the setting state at the operation member, the control unit 205 may make an automatic decision for mode selection. For instance, an automatic decision for mode selection may be made in correspondence to a photographing scene mode, and in such a case, the control unit 205 may select the standard photographing mode for landscape photography or astrophotography, since the need for generating a refocus image based upon an LF image is considered to be low for such photographic scenes.

The control unit 205 may make an automatic decision based upon the conditions of camera 100, and in such a case, it may select the LF photographing mode when the remaining battery power is equal to or lower than a predetermined value, so as to conserve the battery power through a power saving operation by skipping autofocus (AF) operations. In this situation, since LF image data are generated, a refocus image at any focusing position can be later generated.

In step S20, the control unit 205 selects a drive-target image-capturing element before proceeding to step S30. In the standard photographing mode and the dual photographing mode, the control unit 205 designates the first image-capturing element 202 as a drive target. In the LF photographing mode and the dual photographing mode, the control unit 205 designates the second image-capturing element 204 as a drive target. In other words, in the dual photographing mode, both the first image-capturing element 202 and the second image-capturing element 204 are designated as drive targets.

In step S30, the control unit 205 executes an image-capturing operation by driving the image-capturing element(s) selected in step S20 and then the operation proceeds to step S40. In step S40, the control unit 205 issues instructions to the image processing unit 207 so as to engage it in predetermined types of image processing on pixel signals read out from the first image-capturing element 202 or the second image-capturing element 204 or on pixel signals read-out from both the first image-capturing element 202 and the second image-capturing element 204. The operation then proceeds to step S50. The image processing executed in this step may include, for instance, edge enhancement processing, color interpolation processing and white balance processing.

It is to be noted that the processing flow may include a step to be executed prior to step S30, in which a decision is made as to whether or not the shutter has been released, and in such a case, the operation should proceed to step S30 upon deciding that the shutter has been released.

It is to be noted that if the LF photographing mode or the dual photographing mode has been selected through the mode selection in step S10, the control unit 205 generates a refocus image at a specific focusing position or viewpoint through refocus processing executed as the image processing on the image signals read out from the second image-capturing element 204.

In step S50, the control unit 205 causes an image reproduced based upon the data resulting from the image processing to be displayed at the display unit 208. If the dual photographing mode has been selected through the mode selection in step S10, the control unit 205 causes both a standard image and a refocus image to be displayed at the display unit 208. The standard image and the refocus image may be displayed side-by-side or the standard image display and the refocus image display may be switched from one to the other so as to display one image at a time.

In addition, if the LF photographing mode or the dual photographing mode has been selected in step S10 and the refocus image has been displayed at the display unit 208 in step S50, the control unit 205 may engage the image processing unit 207 in refocus processing again in response to a user operation so as to cause a refocus image generated through the second refocus processing to be displayed at the display unit 208. For instance, the user may tap part of the refocus image being displayed at the display unit 208 and in response to the tap, a refocus image focused on a subject area at the tapped position may be displayed at the display unit 208.

As an alternative, the user may move an operation bar (not shown) displayed on the display unit 208, and in response to this user operation, the control unit 205 may cause a refocus image with a different focusing position to be displayed at the display unit 208, with the extent of displacement of the refocus image corresponding to the extent to which the operation bar has been moved.

In step S60, the control unit 205 generates an image file before the operation proceeds to step S70. As explained earlier, the control unit 205 generates an image file containing standard image data if the standard photographing mode has been selected. If the LF photographing mode has been selected, it generates an image file containing LF image data or an image file containing LF image data and refocus image data. In addition, if the dual photographing mode has been selected, it generates an image file containing standard image data and LF image data or an image file containing standard image data, LF image data and refocus image data.

In step S70, the control unit 205 records the image file into the recording medium 206 and then the operation proceeds to step S80. In step S80, the control unit 205 makes a decision as to whether or not to end the session. If, for instance, the main switch has been turned off or a predetermined length of time has elapsed in a non-operating state, the control unit 205 makes an affirmative decision in step S80 and ends the processing in FIG. 6. If, on the other hand, an operation is underway at the camera 100, for instance, the control unit 205 makes a negative decision in step S80 and the operation returns to step S10. Once the operation returns to step S10, the control unit 205 repeatedly executes the processing described above.

The following advantages and operations are obtained through the embodiment described above.

(1) The image sensor in the camera 100 includes a first image-capturing element 202 configured with a plurality of first image-capturing pixels that perform photoelectric conversion for incident light and at each of which part of light is transmitted through, with the color (Ye, Mg or Cy) of light undergoing photoelectric conversion different from the color (B, G or R) of light transmitted through each first image-capturing pixel, a microlens array 203 configured with a plurality of microlenses L, at each of which light in different colors (B, G, R) having been transmitted through a plurality of first image-capturing pixels enters, and a second image-capturing element 204 configured with a plurality of second image pixels PX at which light, having been transmitted through one microlens L among the plurality of microlenses L, enters. This configuration makes it possible to capture color images via both the first image-capturing element 202 and the second image-capturing element 204.

(2) The first image-capturing element 202 in the image sensor described above is configured with first image-capturing pixels, the number of which is greater than the number of the microlenses L. Namely, since light in different colors (B, G, R) having been transmitted through a plurality of first image-capturing pixels enters each microlens L, the extent of color irregularity can be minimized.

(3) In the image sensor described above, the interval between the first image-capturing pixels at the first image-capturing element 202 is set greater than the interval between the second image-capturing pixels PX at the second image-capturing element 204, and as a result, the occurrence of light diffraction can be minimized. Consequently, the quality of images obtained thereat is not compromised.

(4) In the image sensor described above, the interval between the first image-capturing pixels at the first image-capturing element 202 (30 nm or greater) is set so as to reduce the occurrence of visible light diffraction as incident light enters the first image-capturing element 202, and as a result, the quality of images obtained thereat is not compromised.

(5) In the image sensor described above, the plurality of second image-capturing pixels PX in the second image-capturing element 204 perform photoelectric conversion for light in different colors (B, G, R), and thus, a color LF image can be obtained via the second image-capturing element 204.

(6) In the image sensor described above, the colors (B, G, R) of light for which the second image-capturing pixels PX in the second image-capturing element 204 perform photoelectric conversion are different from the colors (Ye, Mg, Cy) of light for which the first image-capturing pixels perform photoelectric conversion. Thus, a structure taking advantage of the characteristics of an organic photoelectric film can be adopted in the image sensor.

(7) In the image sensor described above, the first image-capturing element 202, the microlens array 203 and the second image-capturing element 204 are laminated on one another. This laminated structure makes it possible to provide an integrated image sensor that is easy to handle.

(8) The camera 100 includes the image-capturing elements 202˜204, an image processing unit 207 that generates standard image data based upon first pixel signals generated at the first image-capturing pixels in the first image-capturing element 202 and an image processing unit 207 that generates LF image data expressed with pixels, the number of which is smaller than the number of pixels in the standard image data, based upon second pixel signals generated at the second image-capturing pixels PX in the second image-capturing element 204. This configuration makes it possible to obtain two different types of images through a single-shot image-capturing operation.

(9) The camera 100 includes the control unit 205 that switches from a standard photographing mode in which a standard image is generated based upon standard image data generated at the image processing unit 207, to an LF photographing mode in which a refocus image is generated based upon LF image data generated at the image processing unit 207, and vice versa. Via the control unit, an optimal photographing mode can be selected from the photographing mode for obtaining two different types of images.

(10) The control unit 205 in the camera 100 switches to the standard photographing mode or the LF photographing mode in correspondence to the currently selected photographing scene mode. Since an optimal image-capturing mode is automatically selected based upon a setting state, such as the photographing scene mode, at the camera 100, a user-friendly camera 100 can be provided.

The image sensor achieved in the embodiment as described above may be otherwise described as below.

(1) The image sensor comprises a first image-capturing unit 202 that includes a plurality of first photoelectric conversion units 202B that perform photoelectric conversion for light with a specific wavelength in incident light and at each of which light with another wavelength is transmitted, a plurality of lenses L at which light having been transmitted through the first image-capturing unit enters, i.e., individual lenses L configuring a microlens 203, and a second image-capturing unit 204 configured with a plurality of second photoelectric conversion units 204B disposed in correspondence to each of the plurality of lenses, perform photoelectric conversion for incident light.

(2) The number of the first photoelectric conversion units 202B in the first image-capturing unit 202 configuring the image sensor described in (1) is smaller than the number of the second photoelectric conversion units 204B in the second image-capturing unit 204.

(3) In the image sensor described in (1) and (2) above, the distance between the centers of two first photoelectric conversion units 202B disposed adjacent to each other is greater than the distance between the centers of two second photoelectric conversion units 204B disposed adjacent to each other.

(4) In the image sensor described in (1) through (3) above, the resolution at the first image-capturing unit 202 is lower than the resolution at the second image-capturing unit 204.

(5) In the image sensor described in (3) above, the distance between the centers of two first photoelectric conversion units 202B disposed adjacent to each other is equal to or greater than 4 μm.

(6) In the image sensor described in (1) through (5) above, the plurality of second photoelectric conversion units 204B perform photoelectric conversion for light with wavelengths different from one another.

(7) In the image sensor described in (6) above, the wavelengths of light for which the second photoelectric conversion units 204B perform photoelectric conversion are different from the wavelengths of light for which the first photoelectric conversion units 202B perform photoelectric conversion.

(8) In the image sensor described in (6) above, the wavelengths of light that for which the second photoelectric conversion units 204B perform photoelectric conversion are the same as the wavelengths of light for which the first photoelectric conversion units 202B perform photoelectric conversion.

(9) In the image sensor described in (6) through (8) above, the plurality of first photoelectric conversion units 202B are constituted with organic photoelectric films that perform photoelectric conversion for light having wavelengths different from one another, and the plurality of second photoelectric conversion units 204B are each constituted with a color filter and a photoelectric conversion unit or they are constituted with photoelectric conversion units that receive light at varying wavelengths at different positions along their depth.

(10) The image sensor described in (1) through (9) above includes a lens array 203 configured with a plurality of lenses L, and the first image-capturing unit 202, the lens array 203 and the second image-capturing unit 204 are laminated upon one another.

(11) An image-capturing device comprises the image sensor described in (1) through (10) above, and an image processing unit that generates first image data based upon signals output from the first image-capturing unit 202 and generates second image data expressed with pixels, the number of which is smaller than the number of pixels expressing the first image data, based upon signals read out from the second image-capturing unit 204.

(12) The image-capturing device described in (11) above further comprises a mode selector unit that switches from a first mode, in which a first image is generated based upon the first image data generated at the image processing unit, to a second mode, in which a second image is generated based upon the second image data generated at the image processing unit, and vice versa.

(13) The mode selector unit in the image-capturing device described in (12) above switches from the first mode to the second mode and vice versa in correspondence to a current photographing scene mode setting.

The following variations are also within the scope of the present invention, and one of the variations or a plurality of the variations may be adopted in combination with the embodiment described above.

(Variation 1)

A lens area with a higher refractive index relative to the refractive index of the transmissive substrate 203A may be formed inside the transmissive substrate 203A in the embodiment described above, so as to fulfill the functions of the microlenses L1 through L6 in the lens area. Such a structure makes it possible to obtain better planarization at the surface of the microlens array 203 on the Z axis + side.

By planarizing the surface of the microlens array 203 located on the Z axis + side, a greater bonding surface can be assured for the area over which the surface of the first image-capturing element 202 on the Z axis − side is bonded to the Z axis + side surface of the microlens array 203. Through these measures, an integrated image sensor, which includes the first image-capturing element 202, the microlens array 203 and the second image-capturing element 204 laminated one on the other, can be configured with better ease.

(Variation 2)

The Z axis + side surface of the microlens array 203 may be planarized through another method. For instance, the recessed areas around the microlenses L1 through L6 in FIG. 3 may be filled with a transparent material having a refractive index lower than the refractive index of the material constituting the microlenses L1 through L6 so as to achieve planarization.

In addition, Fresnel lenses may be used in place of the microlenses L1 through L6 so as to configure a lower-profile lens array. In this case, too, the recessed areas surrounding the Fresnel lenses may be filled with a transparent material having a refractive index lower than the refractive index of the material constituting the Fresnel lenses, to obtain planarization.

As a further alternative, the lens array may be constituted with lenticular lenses in place of the microlenses L1 through L6. In this case, too, the recessed areas surrounding the lenticular lenses may be filled with a transparent material having a refractive index lower than the refractive index of the material constituting the lenticular lenses, to obtain planarization.

(Variation 3)

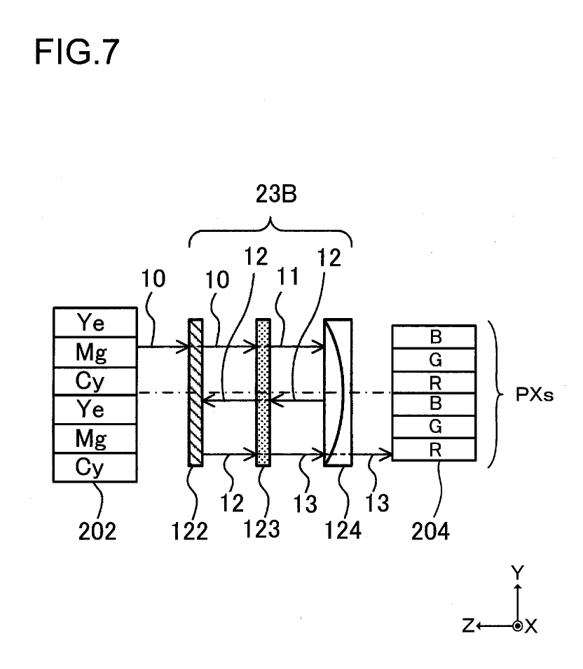

Instead of the microlens array 203 configured with a plurality of microlenses L, the micromirror array configured with a plurality of micromirrors, a patent application for which was submitted by the applicant of the present invention and was internationally disclosed (WO 14/129630) may be used. FIG. 7 presents a schematic sectional view of one of a plurality of micromirrors 23B configuring this micromirror array. The micromirror array is configured by disposing numerous micromirrors 23B in FIG. 7 in a two-dimensional array pattern.

The micromirrors 23B are each configured by laminating a reflective linear polarizer plate 122, a quarter wave (¼ λ) plate 123 and a reflecting mirror 124 in this order starting on the side closer to the first image-capturing element 202. The reflective linear polarizer plate 122 reflects an S-polarized light component in incident light but allows a P-polarized light component to be transmitted through. The quarter wave plate 123 is installed at a 45° angle relative to the axis of the reflective linear polarizer plate 122.

The reflecting mirror 124 is prepared by first forming a concave surface at a transparent substrate and then filling the concavity with an optical adhesive achieving a refractive index equal to that of the transparent substrate. A cholesteric liquid crystal is applied to the concave surface (or on the convex surface on the other side), thereby forming a circularly polarized light separation layer. The circularly polarized light separation layer constituted of the cholesteric liquid crystal allows left-handed circularly polarized light to pass through and reflects right-handed circularly polarized light as right-handed circularly polarized light. The reflecting mirror 124 is installed so that the second image-capturing element 204 is set at its focusing position. Since the concave surface acts as a reflecting mirror for right-handed circularly polarized light, the focal length f is R/2 relative to the radius of curvature R of the concave surface. Since the focal length f of a plano-convex microlens is normally 2R, the use of the reflecting mirror 124 makes it possible to reduce the focal length f to ¼ of the focal length measured in conjunction with the microlens.

The Z axis + side surface and the Z axis − side surface of a micromirror array formed by disposing micromirrors 23B as described above in a two-dimensional array pattern can be planarized. Consequently, a large bonding surface can be assured for the area over which the Z axis − side surface of the first image-capturing element 202 is bonded to the Z axis + side surface of the micromirror array. In addition, a large bonding surface can be assured for the area over which the Z axis + side surface of the second image-capturing element 204 is bonded to the Z axis − side surface of the micromirror array.

(Variation 4)

The wavelength range of light for which the first image-capturing element 202 perform photoelectric conversion may be the RGB wavelength range instead of the YeMgCy wavelength range. The wavelength range of RGB light is normally narrower than the wavelength range of YeMgCy light. This means that if the wavelength range for light for which the first image-capturing element 202 perform photoelectric conversion is set to the RGB wavelength range, a greater wavelength range can be assumed for the complementary colors (YeMgCy) to be transmitted relative to the wavelength range (RGB) for absorption (photoelectric conversion), and that consequently, the amount of light to undergo photoelectric conversion at the second image-capturing element 204 can be increased. This, in turn, makes it possible to raise the signal level of the pixel signals that expresses an LF image obtained at the second image-capturing element 204.

It is to be noted that while the wavelength range of light for which the second image-capturing element 204 perform photoelectric conversion may be the RGB wavelength range, it may be changed to the YeMgCy wavelength range instead.

(Variation 5)

The second image-capturing element 204 may be an image sensor configured with elements that perform photoelectric conversion for light having different wavelengths at varying thickness positions (different positions taken along the Z axis). The use of such an image sensor eliminates the need for the color filter array 204A and also eliminates the need to execute color interpolation processing on the pixel signals read out from the second image-capturing element 204. By eliminating the color filter array 204A, an advantage is obtained in that the amount of light to undergo photoelectric conversion at the second image-capturing element 204 is increased. Consequently, the signal level of the pixel signals expressing an LF image obtained via the second image-capturing element 204 can be raised.

In addition, by eliminating the need for color interpolation processing, an advantage is obtained in that the processing onus on the image processing unit 207 can be lessened.

(Variation 6)

In reference to the embodiment, an example in which the pixel signals resulting from the photoelectric conversion are read out from the first image-capturing element 202 and the second image-capturing element 204 via readout circuits independent of each other. As an alternative, the pixel signals resulting from the photoelectric conversion may be read out from the first image-capturing element 202 and the second image-capturing element 204 via a common readout circuit.

In variation 6, a micro hole 211 is formed at, for instance, the transmissive substrate 203A in the microlens array 203 shown in FIG. 3 and the first image-capturing element 202 and the second image-capturing element 204 are electrically connected by forming a conductor in the micro hole 211. Through these measures, a circuit is connected between the first image-capturing element 202 and the second image-capturing element 204, thereby making it possible to read out the pixel signals resulting from the photoelectric conversion at the first image-capturing element 202 and the second image-capturing element 204 via a common readout circuit.

(Variation 7)

The microlens array 203 in FIG. 3 may include a light-shielding barrier wall 210 formed at the boundary area between each two microlenses adjacent to each other among the microlenses L1 through L6. The presence of such barrier walls 210 will ensure that the light having passed through each of the microlenses L1 through L6 will be received at the pixel group PXs disposed directly to the rear of the particular microlens (along the Z axis − direction) without entering a pixel group PXs disposed to the rear of an adjacent microlens among the microlenses L1 through L6. The barrier walls 210 may be formed by creating a deep groove in a lattice pattern at the microlens array 203 through machining or etching and then by filling the groove with a light-shielding resin.

(Variation 8)

While still images are captured in the embodiment described above, the present invention may be adopted in applications in which movie images are captured.

While an embodiment and variations thereof have been described above, the present invention is in no way limited to the particulars of these examples. Another mode conceivable within the scope of the technical teachings of the present invention is also within the scope of the present invention.

Accordingly, the following image sensors and image-capturing devices are also within the scope of the present invention.

(1) An image sensor comprising a first image-capturing unit that includes a plurality of first image-capturing pixels, at each of which part of incident light undergoes photoelectric conversion while part of the incident light is transmitted through with the color of the light undergoing photoelectric conversion and the color of the light being transmitted through being different from each other, a microlens array configured with a plurality of microlenses at each of which light in different colors having been transmitted through a plurality of first image-capturing pixels enters, and a second image-capturing unit configured with a plurality of second image-capturing pixels at which light having been transmitted through one microlens among the plurality of microlenses enters.

(2) The image sensor described in (1) above, having the first image-capturing pixels in a quantity greater than the quantity of microlenses.

(3) The image sensor described in (1) and (2) above, with the first image-capturing pixels disposed over an interval greater than the interval with which the second image-capturing pixels are disposed.

(4) The image sensor described in (3) above, with the first image-capturing pixels disposed over an interval at which the occurrence of light diffraction as incident light enters the first image-capturing unit is reduced.

(5) The image sensor described in (1) through (4) above, in which light in colors different from one another for which the plurality of second image-capturing pixels perform photoelectric conversion.

(6) The image sensor described in (5) above, in which the colors of light for which the second image-capturing pixels perform photoelectric conversion are different from the colors of light for which the first image-capturing pixels perform photoelectric conversion.

(7) The image sensor described in (5) above, in which the colors of light for which the second image-capturing pixels perform photoelectric conversion are the same as the colors of the light for which the first image-capturing pixels perform photoelectric conversion.

(8) The image sensor described in (5) through (7) above, with the first image-capturing unit thereof configured with organic photoelectric films that perform photoelectric conversion for light in different colors or with color filters and an organic photoelectric film, and the second image-capturing unit thereof configured with color filters and light-receiving units with light-receiving elements that receive light in different colors at different depth-wise positions.

(9) The image sensor described in (1) through (8) above, with the first image-capturing unit, the microlens array and the second image-capturing unit laminated one on another.

(10) An image-capturing device comprising the image sensor described in (1) through (9) above, a first image data generation unit that generates first image data based upon first signals generated via the first image-capturing pixels, and a second image data generation unit that generates second image data expressed with a smaller number of pixels than the number of pixels expressing the first image data, based upon second signals generated at the second image-capturing pixels.

(11) The image-capturing device described in (10) above, further comprising a mode selector unit that switches from a first mode, in which a first image is generated based upon the first image data generated via the first image data generation unit, to a second mode, in which a second image is generated based upon the second image data generated via the second image data generation unit, and vice versa.

(12) The image-capturing device described in (11) above, the mode selector unit which switches from the first mode to the second mode and vice versa in correspondence to a current image-capturing scene mode setting.

The disclosure of the following priority application is herein incorporated by reference:

Japanese Patent Application No. 2015-188248 filed Sep. 25, 2015

### REFERENCE SIGNS LIST

100 . . . camera, 201 . . . image-capturing lens, 202 . . . first image-capturing element, 203 . . . microlens array, 204 . . . second image-capturing element, 205 . . . control unit, 207 . . . image processing unit, 208 . . . display unit, L1-L6 . . . microlens, PX . . . pixel at second image-capturing element 204, PXs . . . pixel group at second image-capturing element 204

1. An image sensor, comprising:
a first image-capturing unit that includes a plurality of first photoelectric conversion units that perform photoelectric conversion for light at a part of wavelength in incident light and at each of which light at another wavelength in the incident light is transmitted;
a plurality of lenses at which the light having been transmitted through the first image-capturing unit enters; and
a second image-capturing unit that includes a plurality of second photoelectric conversion units, disposed in correspondence to each of the plurality of lenses, that perform photoelectric conversion for incident light.

2. The image sensor according to claim 1, wherein:
a quantity of the first photoelectric conversion units at the first image-capturing unit is smaller than a quantity of the second photoelectric conversion units at the second image-capturing unit.

3. The image sensor according to claim 1, wherein:
a distance between centers of two first photoelectric conversion units disposed adjacent to each other is greater than a distance between centers of two second photoelectric conversion units disposed adjacent to each other.

4. The image sensor according to claim 1, wherein:
resolution at the first image-capturing unit is lower than resolution at the second image-capturing unit.

5. The image sensor according to claim 3, wherein:
the distance between the centers of the two first photoelectric conversion units disposed adjacent to each other is equal to or greater than 4 μm.

6. The image sensor according to claim 1, wherein:
the plurality of second photoelectric conversion units perform photoelectric conversion for light at wavelengths different from one another.

7. The image sensor according to claim 6, wherein:
the wavelengths of light for which the second photoelectric conversion units perform photoelectric conversion are different from wavelengths of light for which the first photoelectric conversion units perform photoelectric conversion.

8. The image sensor according to claim 6, wherein:
the wavelengths of light for which the second photoelectric conversion units perform photoelectric conversion match wavelengths of light for which the first photoelectric conversion units perform photoelectric conversion.

9. The image sensor according to claim 6, wherein:
the plurality of first photoelectric conversion units are constituted with organic photoelectric films that perform photoelectric conversion for light at different wavelengths, and the plurality of second photoelectric conversion units are constituted with color filters and photoelectric conversion units or constituted with photoelectric conversion units that receive light at different wavelengths at different depth-wise positions.

10. The image sensor according to claim 1, further comprising:
a lens array that includes the plurality of lenses, wherein:
the first image-capturing unit, the lens array and the second image-capturing unit are laminated one on another.

11. An image-capturing device, comprising:
the image sensor according to claim 1; and
an image processing unit that generates first image data based upon signals from the first image-capturing unit and generates second image data, expressed with fewer pixels than the first image data, based upon signals from the second image-capturing unit.

12. The image-capturing device according to claim 11, further comprising:
a mode selector unit that switches from a first mode, in which a first image is generated based upon the first image data generated via the image processing unit, to a second mode, in which a second image is generated based upon the second image data generated via the image processing unit, and vice versa.

13. The image-capturing device according to claim 12, wherein:
the mode selector unit switches from the first mode to the second mode and vice versa in correspondence to a current image-capturing scene mode setting.
